(19) United States
(12) Patent Application Publication
(10) Pub. No.: US 2008/0299767 A1
(43) Pub. Date: Dec. 4, 2008

(54) Method for Forming a Semiconductor Device Having a Salicide Layer

(75) Inventors: Ryan Ross, Grenoble (FR); Greg Braeckelmann, Grenoble (FR)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freecale Semiconductor, Inc, Austin, TX (US)

(21) Appl. No.: 12/094,570

(22) PCT Filed: Nov. 21, 2005
(86) PCT No.: PCT/EP2005/013521

§ 371 Date: May 21, 2008

(51) Int. Cl. H01L 21/3205

(52) U.S. Cl. 438/664; 257/E21.295

(57) ABSTRACT

A method for forming a semiconductor device and selectively forming a salicide layer is described. In one embodiment, the method includes depositing a metal layer over a semiconductor substrate having a first area and a second area, wherein the first area and the second area include silicon, removing the metal layer over the second gate electrode, and reacting the metal layer with the first area to form a salicide layer over the first area. In one embodiment, the first area and the second area include a first gate electrode and a second gate electrode, respectively.

### FIELD OF THE INVENTION

This invention relates generally to forming a semiconductor device, and more specifically, to forming a salicide layer.

### BACKGROUND OF THE INVENTION

In semiconductor manufacturing, semiconductor devices are usually made with lightly-doped drains at the junction with a channel and a relatively higher doped drain region used for making contact. The sources are made in the same way. The contact to the drain is made using a silicide, which is a silicon metal compound. This material is also called salicide referring to the particular integration used called ‘self aligned silicide’ or ‘salicide’. The salicide is the contact point for the source and the drain of the semiconductor device.

One approach for forming the salicide involves depositing a metal layer over the semiconductor wafer, reacting the metal layer with silicon-containing regions to form a metal silicide, and then removing any unreacted portions of the metal layer from non-silicon surfaces. This approach forms the salicide over all areas that include silicon. However, sometimes it is desired that salicide is not formed over some silicon-containing areas so that the desired high sheet resistance is not diminished. For example, salicide may not be formed on silicon-containing resistors in analog and I/O circuitry.

An approach for forming salicide over some silicon-containing areas and not over others includes coating the entire semiconductor wafer with an oxide layer and a nitride layer formed over the oxide layer. The oxide and nitride layers are removed in the areas where salicide will subsequently be formed. The metal layer is formed over the semiconductor wafer and reacts with the silicon-containing areas of the semiconductor wafer that are exposed by the oxide and nitride layers. However, it is difficult to remove the oxide and nitride layers. In addition, the nitride layer often is removed incompletely during processing and causes defectivity issues. Therefore, a need exists for a manufacturable method to form salicide over some silicon-containing regions and not over others.

### SUMMARY OF THE INVENTION

The present invention provides a method for forming a salicide layer for fabricating a semiconductor device as described in the accompanying claims.

### BRIEF DESCRIPTION OF THE DRAWINGS

The present invention is illustrated by way of example and not limited by the accompanying Figures, in which like references indicate similar elements, and in which:

FIG. 1 is a cross-section of a portion of a semiconductor substrate having a first transistor and a second transistor in accordance with one embodiment of the invention, given by way of example,

FIG. 2 is the semiconductor substrate of FIG. 1 after forming a metal layer in accordance with one embodiment of the invention, given by way of example,

FIG. 3 is the semiconductor substrate of FIG. 2 after forming an optional protective layer in accordance with one embodiment of the invention, given by way of example,

FIG. 4 is the semiconductor substrate of FIG. 3 after forming a resist layer over the semiconductor substrate in accordance with one embodiment of the invention, given by way of example,

FIG. 5 is the semiconductor substrate of FIG. 4 after patterning the resist layer in accordance with one embodiment of the invention, given by way of example,

FIG. 6 is the semiconductor substrate of FIG. 5 after removing at least a portion of the metal layer in accordance with one embodiment of the invention, given by way of example,

FIG. 7 is the semiconductor substrate of FIG. 6 after removing the resist, in accordance with one embodiment of the invention, given by way of example,

FIG. 8 is the semiconductor substrate of FIG. 7 after forming salicide regions and selectively removing unreacted metal, in accordance with one embodiment of the invention, given by way of example, and

FIG. 9 is the semiconductor substrate of FIG. 8 after forming vias and an interlevel dielectric in accordance with one embodiment of the invention, given by way of example.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE PREFERRED EMBODIMENTS

The embodiments of the invention described below provide a manufacturable method for selectively forming a salicide layer. For example in one embodiment, the method for forming a semiconductor device includes providing a semiconductor substrate, depositing a metal layer over the semiconductor substrate, patterning the metal layer to remove it in areas where salicide is not to be formed, and reacting the metal layer to form a salicide layer after patterning. Therefore, a metal layer is patterned before it is reacted so that some areas that include silicon are left unsalicided.

Another example includes forming a semiconductor device by determining a first region of a semiconductor substrate, wherein the first region is a region where salicide will be subsequently formed, determining a second region wherein the second region is a region where salicide will not be subsequently formed, forming a metal layer over the semiconductor substrate, removing the metal layer in the second region, and reacting the metal layer to form a salicide in the first region. However, the embodiments of the invention are better understood by turning to the figures.

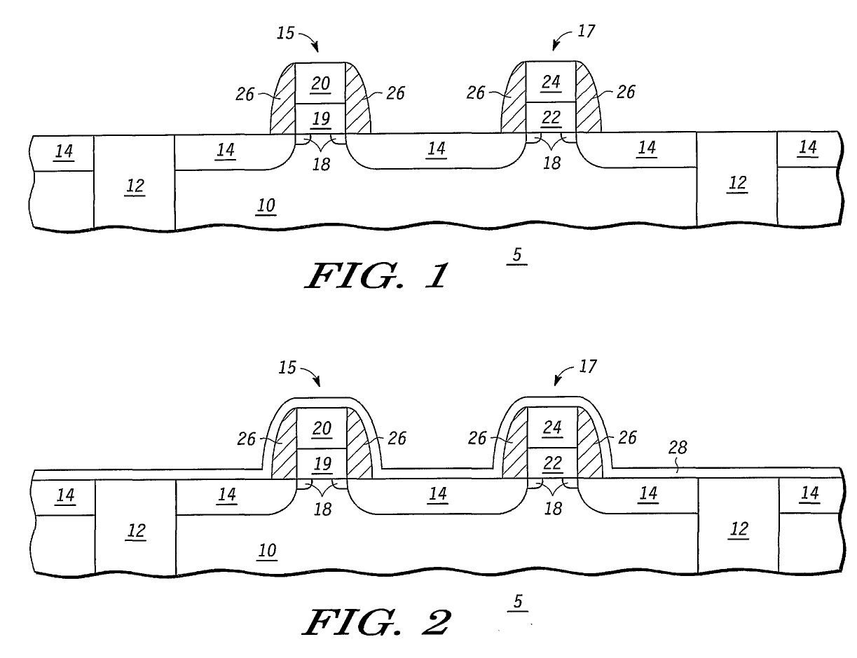

FIG. 1 illustrates a portion of a semiconductor device 5. The semiconductor device 5 includes a first gate stack 15 and a second gate stack 17 formed over a semiconductor substrate 10, which includes isolation regions 12, source/drain regions 14, and extension regions 18. The semiconductor substrate 10 can be any semiconductor material or combinations of materials, such as gallium arsenide, silicon germanium, silicon-on-insulator (SOI) (e.g., fully depleted SOI (FDSOI)), silicon, monocrystalline silicon, the like, and combinations of the above. However, for salicide to be formed over a portion of the semiconductor substrate 10 layer this portion will include silicon. The semiconductor substrate 10 is preferably silicon doped to N- so as to form an N well region. This may be achieved by starting with a bulk P-substrate and selectively doping active regions to N- for formation of P channel transistors in which case semiconductor substrate 10 has a well region (not shown). The isolation regions 12 electrically isolate the well regions within the semiconductor substrate 10. In one embodiment, the isolation regions 12 are shallow trench isolation regions that are formed by etching the semiconductor device, depositing or growing an insulating layer such as silicon dioxide, and planarizing the insulating layer.

After forming the isolation regions 12 a gate dielectric layer and a gate electrode layer are deposited over the semiconductor substrate 10 and subsequently patterned to form gate dielectrics, such as the first gate dielectric 19 or the second gate dielectric 22, and gate electrodes, such as the first gate electrode 20 and the second gate electrode 24. In a preferred embodiment, the gate dielectric layer is a high dielectric constant (hi-k) dielectric or a combination of materials, where at least one of the materials is a hi-k dielectric. Any hi-k dielectric may be used, such as hafnium oxide, zirconium oxide, the like, and combinations of the above. In one embodiment, the gate dielectric layer includes silicon dioxide or the like. For example, the gate dielectric layer may be hafnium oxide with an underlying layer of silicon dioxide, which may be a native silicon dioxide. The gate electrode layer can be any material such as a metal, metal alloy, or polysilicon, which may subsequently be doped. However, for salicide to be formed over a portion of the gate electrode layer this portion will include silicon. The gate dielectric layer and the gate electrode layer may be formed by any process, such as thermal growth, chemical vapor deposition (CVD), physical vapor deposition (PVD), atomic layer deposition (ALD), the like, and combinations of the above. The first gate dielectric 19 and the first gate electrode 20 form the first gate stack 15, and the second gate dielectric 22 and the second gate electrode 24 form the second gate stack 17.

After forming the first and second gate stacks 15 and 17, regions 18 and portions of regions 14 may be formed adjacent the first and second gate stacks 15 and 17 by ion implantation. Regions 18 and portions of the regions 14 are adjacent to the first and second gate stacks 15 and 17 because the first and second gate stacks 15 and 17 act as a mask during the implantation process that forms these regions. The region in the semiconductor substrate 10 between the regions 18 is where the channel of the transistors is to be located. After forming the regions 18, which in one embodiment are extension regions, and possibly portions of the regions 14, sidewall spacers 26 are formed. In one embodiment, the spacers are formed by forming an insulating layer over the semiconductor substrate and then anisotropically etching the insulating layer. Any other process, however, can be used and the sidewall spacers 26 may include more than one layer. For example, the sidewall spacers 26 could include an oxide layer under a nitride layer.

The sidewall spacers 26 in conjunction with the first and second gate stacks 15 and 17 are then used as a mask to form the regions (or rest of the regions) 14, which are the source/drain regions, using ion implantation. Conventional ion implantation processes can be used to form the extensions 18 and the source/drain regions 14. For example, the source/drain regions 14 may be formed by implanting boron using boron difluoride. Afterwards, annealing is performed to activate the implants and expanding the regions, as known in the art.

After forming the structure shown in FIG. 1, a preclean is performed to remove any oxides that may be on the exposed surface of the semiconductor device 5. As will be better understood after further explanation, oxide is removed so that the subsequently formed metal layer 28 is formed directly on the first gate electrode 20 and the source/drain regions 14 allowing a salicide to be formed. In one embodiment, the preclean includes a wet chemical etch using hydro-fluoric acid, followed by an argon sputter etch. The pre-clean can be a wet chemical etch that removes oxide, an argon sputter etch, a remote plasma etch using NH₃/NF₃ chemistry, or another dry etch used for silicon dioxide.

As shown in FIG. 2, a metal layer 28 is formed over the semiconductor device 5. In one embodiment, the metal layer 28 is formed directly on the semiconductor device 5. The metal layer 28 can be formed by any process, such as PVD, CVD, ALD, the like, and combinations of the above. The deposition is a blanket process because the metal layer 28 is formed over all exposed areas of the semiconductor device 5 and is not selectively deposited. The temperature of the deposition should be such that the metal layer 28 will not react with any underlying layers. Thus, the temperature should be below the salicidation temperature for the metal layer 28. In one embodiment, the metal layer 28 is formed at room temperature.

Furthermore, all processing after depositing the metal layer 28 and up until the salicidation process (described below) should occur at temperatures less than the temperature at which the metal starts diffusion (i.e., the silicide formation temperature) for the metal layer 28 so that salicidation does not occur prematurely. For example, if the metal layer is nickel the temperature should be less than 120 degrees Celsius and if the metal layer is cobalt the temperature should be less than 400 degrees Celsius, or even 350 degrees Celsius.

During the deposition process, a thin layer (e.g., a few atoms thick) may be formed between the metal layer 28 and the first or second gate electrodes 20 and 24. For example, if the metal layer 28 is nickel and the first and second gate electrodes 20 and 24 are polysilicon, a thin layer of nickel silicide may be formed under the metal layer 28. However, this layer is so thin that it will not change the resistance of the final ‘unsilicided’ resistor structure that is being formed.

The metal layer 28 includes the metal that will be used to form the salicide. In one embodiment, the metal layer 28 includes cobalt, nickel, palladium, platinum, titanium, or tungsten. In one embodiment, the metal layer 28 includes a single metal, such as cobalt, and in another embodiment, the metal layer 28 includes more than one metal and thus, is a metal alloy, such as nickel platinum. The thickness of the metal layer 28 depends on the material chosen and the lengths of the first and second gate electrodes 20 and 24. For example, for technology with gate electrodes lengths of 65 nanometers or less, if the metal layer 28 is nickel the thickness may be approximately 70 to 100 Angstroms and if the metal is cobalt the thickness may be approximately 90 to 150 Angstroms.

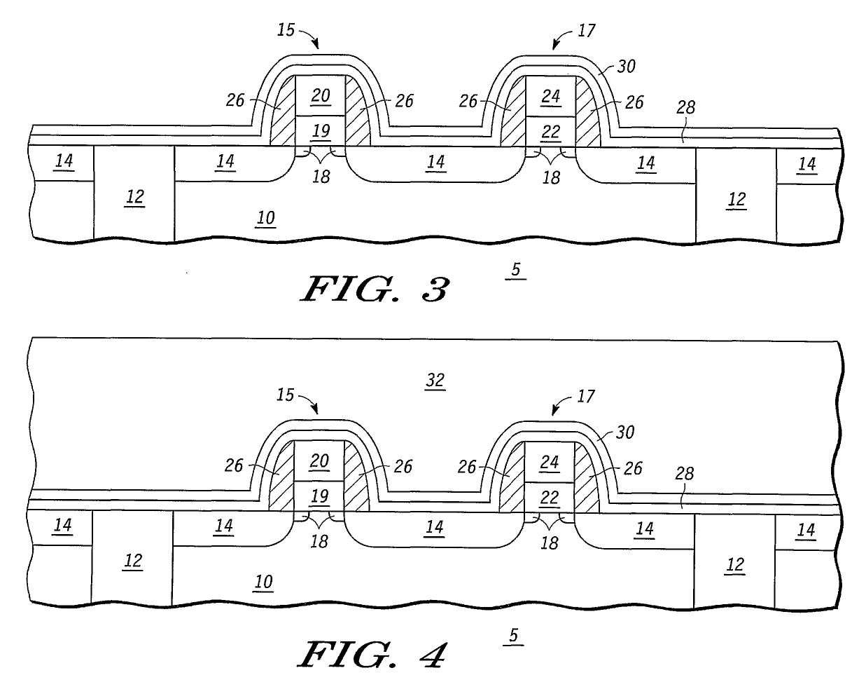

After forming the metal layer 28, a protective layer 30 is optionally formed as shown in FIG. 3. The protective layer 30, if formed, protects the metal layer 28 from oxidation during subsequent processing. As will better be understood after further explanation, the protective layer 30 is a sacrificial layer. In one embodiment, the protective layer 30 is titanium nitride or tantalum nitride and may be approximately 25 to 200 Angstroms thick. However, the thickness of the protective layer 30 also depends on the material chosen and the length of the gate electrodes. The protective layer 30 may be formed by any process, such as PVD, CVD, ALD, the like, or combinations of the above.

As shown in FIG. 4, after forming the metal layer 28 and the protective layer 30 (if present), a resist layer 32 is formed over the semiconductor device 5. The resist layer is deposited by any method; in a preferred embodiment, the resist layer is spun-on. In one embodiment, the thickness of the resist layer 32 is approximately 400-700 nm.

After forming the resist layer 32 it is patterned and becomes a patterned resist layer 34 having an opening 36, as shown in FIG. 5. The resist layer 32 is patterned by using photolithography. During the photolithography process, a mask having a pattern so that the opening 36 is formed is used. After patterning, the resist layer is etched so that the opening 36 is formed. The opening 36 exposes a portion of the protective layer 30, if present, that is over the second gate stack 17, which is the gate stack where salicide is not subsequently formed. In other words in the embodiment illustrated in the figures, it is desired that the salicide not be formed over the second gate stack 17. If the protective layer 30 is not present, a portion of the metal layer 28 over the second gate stack 17 will be exposed by the opening 36.

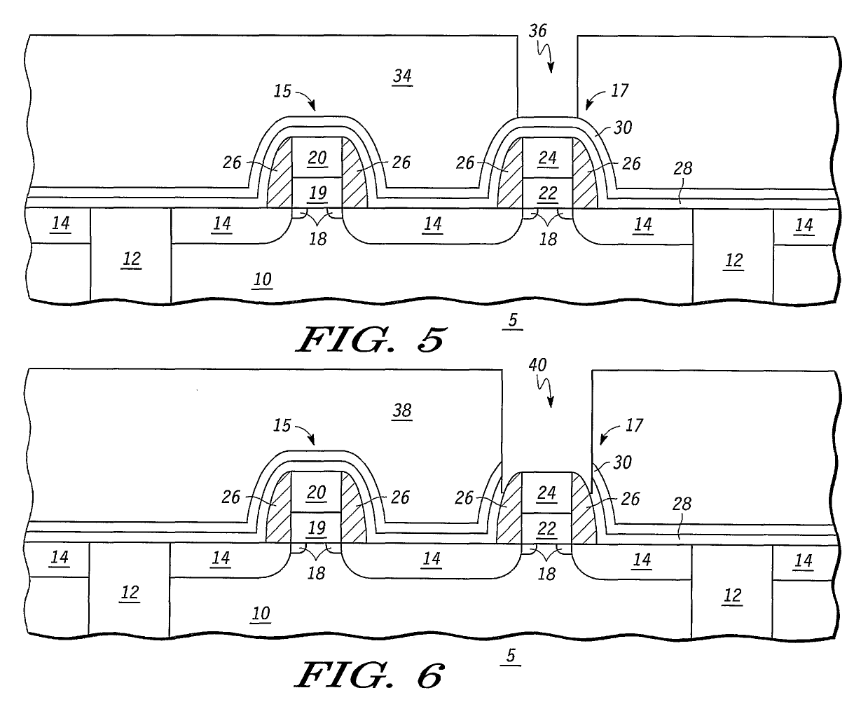

As shown in FIG. 6, after forming the opening 36 portions of the protective layer 30, if present, and the metal layer 28 that either exposed by the opening 36 or are under the opening 36 are removed. In the process of removing portions of the metal layer 28 and the protective layer 30, if present, the opening 36 may be enlarged to form an enlarged opening 40 and the modified patterned resist layer 38, as shown in FIG. 6. The portions of the protective layer 30, if present, and the metal layer 28 may be removed by a wet etch, a dry etch, the like, or combinations of the above. In one embodiment, a wet etch is performed using H₂SO₄ and H₂O₂, if the metal layer 28 is nickel and the protective layer 30 is titanium nitride. Because the etch rate of this chemistry for nickel salicide is approximately 30 times less than the etch rate of nickel, if a thin nickel salicide layer is formed underneath the metal layer 28, it is unlikely that it will be removed. Even if the nickel salicide layer is not removed, it is believed that it would be too thin (e.g., greater than or less than approximately 30 Angstroms) to affect the resistivity of the underlying second gate electrode 24.

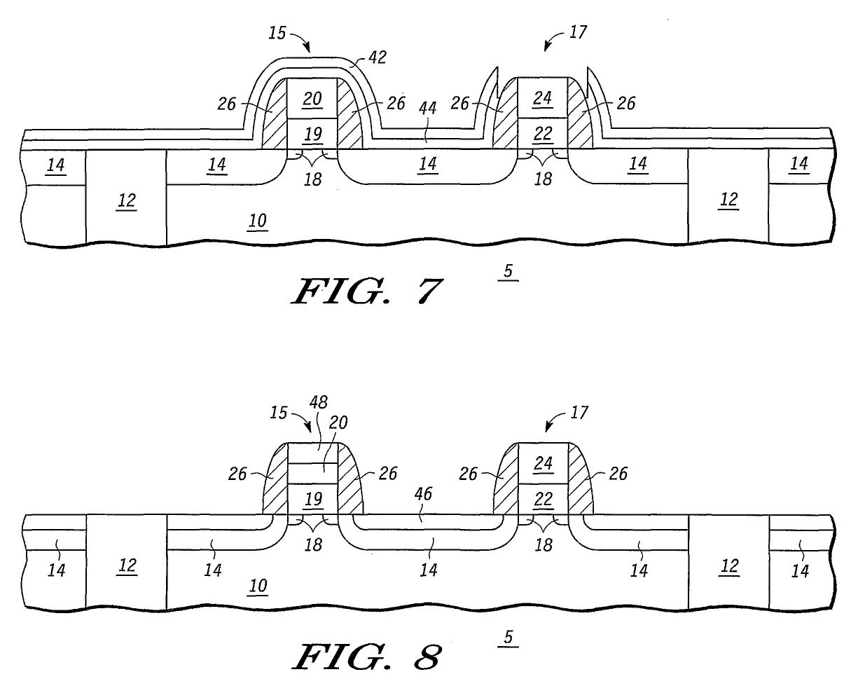

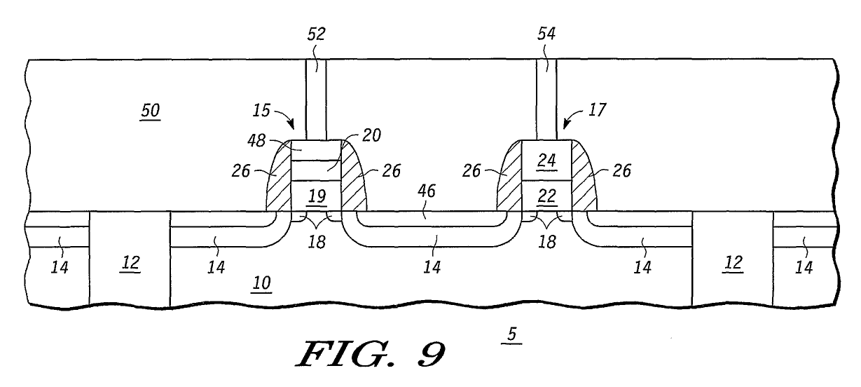

After removing portions of the metal layer 28 and the protective layer 30, if present, the resist is removed, as shown in FIG. 7. In one embodiment, the resist is removed through an ash process that uses an oxygen environment.

As shown in FIG. 8 after removing the resist, the first salicide region 48 and the second salicide regions 46 are formed. The first and second salicide regions 48 and 46 are formed by a heating step or anneal. In one embodiment, the anneal is performed in an inert ambient, such as nitrogen, at a temperature of approximately 425-550 degrees Celsius for approximately 1-120 seconds for cobalt or approximately 250-350 degrees Celsius for approximately 1-120 seconds for nickel. Salicide will be formed where the metal layer 28 is over a layer, such as polysilicon, that includes silicon and will react with the metal layer 28 and form a silicide. For example, even if the spacers 26 include silicon nitride the silicon will not react with the metal layer 28 to form a salicide over the spacers 26. The annealing results in the formation of the first salicide region 48 over the first gate electrode 20 and the second salicide regions 46 over the source/drain regions 14. These salicide regions 48 and 46 are contacts that are effective for making an electrical connection as desired; in addition, they reduce the sheet resistance of the underlying material. No silicide is formed over the second gate electrode 24 because the metal layer 28 overlying the second gate electrode 24 was removed prior to the heating step so that the high sheet resistance, for example, that is desired for the second gate stack 17 is achieved.

After forming the salicide regions 48 and 46, portions of the metal layer 28 that were not salicided are removed. This may be achieved using an etchant, such as piranha, that is selective between the metal, which is nickel in this case, and the metal salicide, which is nickel salicide in this case. The device may then be subjected to an additional anneal to complete the salicide formation if so desired. In one embodiment, the anneal is performed in an inert ambient, such as nitrogen, at a temperature of approximately 650-850 degrees Celsius for approximately 20-120 seconds for cobalt or approximately 370-450 degrees Celsius for approximately 1-120 seconds for nickel. This last anneal, however, may or may not be necessary depending on the process technology used in device fabrication.

After the clean and optional second anneal, semiconductor device fabrication is continued using conventional processing. For example, an interlevel dielectric (ILD) may be formed over the semiconductor device 5 and patterned to form openings over the first and second gate stacks 15 and 17. The openings may then be filled with conductive material to form a first via 52 over the first gate stack 15 and a second via 54 over the second gate stack 17. Because the first salicide region 48 was formed over the first gate stack 15, the first via 52 is in contact with the first salicide region 48, wherein the second via 54 is not in contact with any salicide region. Instead, the second via 54 is in contact with the second gate electrode 24. Subsequent processing may be continued to form interconnects and other features.

A skilled artisan should appreciate that although the figures illustrate using the above methods to selectively form salicide over a gate electrode, these methods can be used over any features, such as over active silicon-including areas in addition to or instead of over the gate electrode.

By now it should be appreciated that there has been provided a simple manufacturable method for selectively forming some transistors with salicide and others (e.g., resistors) without salicide. By depositing a blanket metal layer over the entire wafer after all the transistors (which in one embodiment, includes the source/drain regions) are formed, the risk of not forming salicide in a desired area is mitigated. Furthermore, the embodiments of this invention eliminate the defectivity and process marginality issues associated with depositing and patterning nitride and oxide layers to selectively form salicide over transistors or any feature or layer that includes silicon

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. Moreover, the terms “front”, “back”, “top”, “bottom”, “over”, “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

1. A method for forming a semiconductor device, comprising:
blanket depositing a metal layer over a semiconductor substrate having a first area and a second area, wherein the first area and the second area include silicon;
removing the metal layer over the second area; and
reacting the metal layer with the first area to form a salicide layer over the first area.

2. The method of claim 1, wherein the first area includes a first gate electrode and the second area includes a second gate electrode.

3. The method as claimed in claim 1, further including:
forming a mask layer over the metal layer; and
patterning the mask layer to expose the metal layer over the area.

4. The method as claimed in claim 1, further including:
depositing a protective layer over the metal layer; and
removing the protective layer over the second area.

5. The method as claimed in claim 1, wherein the metal layer includes a metal alloy.

6. The method as claimed in claim 1, wherein the metal layer includes an element selected from the group consisting of cobalt and nickel.

7. The method as claimed in claim 4, wherein the protective layer includes an element selected from the group consisting of nickel, tantalum, and titanium.

8. The method as claimed in claim 1, wherein depositing occurs at a temperature less than 400 degrees Celsius.

9. The method as claimed in claim 1, wherein reacting includes annealing the semiconductor substrate.

10. The method as claimed in claim 1, further including removing portions of the metal layer that do not form the salicide.

11. The method as claimed in claim 2, further including:
forming a mask layer over the metal layer; and
patterning the mask layer to expose the metal layer over the area.

12. The method as claimed in claim 2, further including:
forming a mask layer over the metal layer; and
patterning the mask layer to expose the metal layer over the area.

13. The method as claimed in claim 2, further including:
depositing a protective layer over the metal layer; and
removing the protective layer over the second area.

14. The method as claimed in claim 2, wherein the metal layer includes a metal alloy.

15. The method as claimed in claim 2, wherein reacting includes annealing the semiconductor substrate.

16. The method as claimed in claim 3, further including:
depositing a protective layer over the metal layer; and
removing the protective layer over the second area.

17. The method as claimed in claim 2, wherein the metal layer includes an element selected from the group consisting of cobalt and nickel.

18. The method as claimed in claim 4, wherein depositing occurs at a temperature less than 400 degrees Celsius.

19. The method as claimed in claim 13, wherein depositing occurs at a temperature less than 400 degrees Celsius.

20. The method as claimed in claim 3, wherein the metal layer includes a metal alloy.
